(19) United States
(12) Patent Application Publication
(10) Pub. No.: US 2016/0255717 A1
(43) Pub. Date: Sep. 1, 2016

(54) MULTILAYER WIRING BOARD

(71) Applicant: IBIDEN CO., LTD., Ogaki-shi (JP)

(72) Inventors: Toshiki FURUTANI, Ogaki-shi (JP); Yasushi INAGAKI, Ogaki-shi (JP); Shunsuke SAKAI, Ogaki-shi (JP)

(73) Assignee: IBIDEN CO., LTD., Ogaki-shi (JP)

(21) Appl. No.: 15/052,009

(22) Filed: Feb. 24, 2016

(30) Foreign Application Priority Data
Feb. 27, 2015 (JP) 2015-038782

(51) Int. Cl. H05K 1/02; H05K 1/18

(52) U.S. Cl. CPC H05K 1/0298; H05K 1/0296; H05K 1/18

(57) ABSTRACT

A multilayer wiring board includes wiring bodies each including an insulating layer, a conductor layer embedded in the insulating layer and having exposed surface on first surface of the insulating layer, and a conductor post formed on embedded surface of the conductor layer on the opposite side and having end surface on second surface of the insulating layer. The bodies include first and second bodies forming outermost layers on the opposite sides, the exposed surface is recessed from the first surface of the insulating layer in the first body, the end surface is recessed from the second surface in the second body in recess amount greater than that of the exposed surface in the first body, the post of the first body has the exposed surface bonded to the conductor layer of an adjacent body, the second body has the conductor layer bonded to the post of an adjacent body.

### CROSS-REFERENCE TO RELATED APPLICATIONS

The present application is based upon and claims the benefit of priority to Japanese Patent Application No. 2015-038782, filed Feb. 27, 2015, the entire contents of which are incorporated herein by reference.

### BACKGROUND OF THE INVENTION

1. Field of the Invention

The present invention relates to a multilayer wiring board that is formed by laminating multiple wiring bodies each including a resin insulating layer, a conductor layer and a conductor post.

2. Description of Background Art

Japanese Patent Laid-Open Publication No. HEI 10-13028 describes a multilayer printed wiring board that includes single-sided circuit boards. Single-sided circuit boards are laminated on both sides of a core substrate via adhesive layers. The single-sided circuit boards each include an insulating substrate, a conductor circuit (conductor layer) that is formed by patterning by etching a metal foil on a surface on one side of the insulating substrate, and a conductor post that is formed from a conductive paste filled in a through hole in the insulating substrate. A front end of the conductor post protrudes from a surface on the other side of the insulating substrate. The entire contents of this publication are incorporated herein by reference.

### SUMMARY OF THE INVENTION

According to one aspect of the present invention, a multilayer wiring board includes wiring bodies each including a resin insulating layer, a conductor layer embedded in the resin insulating layer such that the conductor layer has an exposed surface exposed from a first surface of the resin insulating layer, and a conductor post including a plating material and formed on an embedded surface of the conductor layer on the opposite side with respect to the exposed surface of the conductor layer such that the conductor post is penetrating through the resin insulating layer and has an end surface exposed from a second surface of the resin insulating layer on the opposite side with respect to the first surface. The wiring bodies include a first wiring body forming a first outermost layer and a second wiring body forming a second outermost layer on the opposite side with respect to the first outermost layer and is laminated such that the first wiring body electrically connects to the second wiring body, the first wiring body is formed such that the exposed surface of the conductor layer is recessed from the first surface of the resin insulating layer of the first wiring body, the second wiring body is formed such that the end surface of the conductor post is recessed from the second surface of the resin insulating layer in a recess amount which is greater than a recess amount of the exposed surface of the conductor layer in the first wiring body, and the wiring bodies are laminated such that the conductor post of the first wiring body has the exposed surface directly bonded to the conductor layer of an adjacent one of the wiring bodies and that the second wiring body has the conductor layer directly bonded to the conductor post of an adjacent one of the wiring bodies.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a multilayer wiring board according to an embodiment of the present invention;

FIG. 2A is an enlarged view of a conductor post of the multilayer wiring board illustrated in FIG. 1;

FIG. 2B is a cross-sectional view illustrating another example of a positional relation between conductor posts of the multilayer wiring board illustrated in FIG. 1;

FIG. 3A illustrates a layout of conductor posts of a second wiring body of the multilayer wiring board according to an embodiment of the present invention;

FIG. 3B illustrates an example of a pattern that is formed in a conductor layer of a first wiring body of the multilayer wiring board illustrated in FIG. 3A;

FIG. 4 is a cross-sectional view of a multilayer wiring board according to another embodiment of the present invention;

FIG. 5A is a cross-sectional view illustrating another example of a positional relation between conductor posts of the multilayer wiring board illustrated in FIG. 4;

FIG. 5B is a cross-sectional view illustrating another example of a positional relation between conductor posts of the multilayer wiring board illustrated in FIG. 4;

FIG. 5C is a cross-sectional view illustrating another example of a positional relation between conductor posts of the multilayer wiring board illustrated in FIG. 4;

FIG. 6A illustrates an example of a method for manufacturing the multilayer wiring board illustrated in FIG. 1;

FIG. 6B illustrates an example of the method for manufacturing the multilayer wiring board illustrated in FIG. 1;

FIG. 6C illustrates an example of the method for manufacturing the multilayer wiring board illustrated in FIG. 1;

FIG. 6D illustrates an example of the method for manufacturing the multilayer wiring board illustrated in FIG. 1;

FIG. 6E illustrates an example of the method for manufacturing the multilayer wiring board illustrated in FIG. 1;

FIG. 6F illustrates an example of the method for manufacturing the multilayer wiring board illustrated in FIG. 1;

FIG. 6G illustrates an example of the method for manufacturing the multilayer wiring board illustrated in FIG. 1;

FIG. 6H illustrates an example of the method for manufacturing the multilayer wiring board illustrated in FIG. 1;

FIG. 6I illustrates an example of the method for manufacturing the multilayer wiring board illustrated in FIG. 1;

FIG. 6J illustrates an example of the method for manufacturing the multilayer wiring board illustrated in FIG. 1;

FIG. 6K illustrates an example of the method for manufacturing the multilayer wiring board illustrated in FIG. 1;

FIG. 6L illustrates an example of the method for manufacturing the multilayer wiring board illustrated in FIG. 1; and

FIG. 7 illustrates an example of a method for manufacturing the multilayer wiring board illustrated in FIG. 4.

### DETAILED DESCRIPTION OF THE EMBODIMENTS

The embodiments will now be described with reference to the accompanying drawings, wherein like reference numerals designate corresponding or identical elements throughout the various drawings.

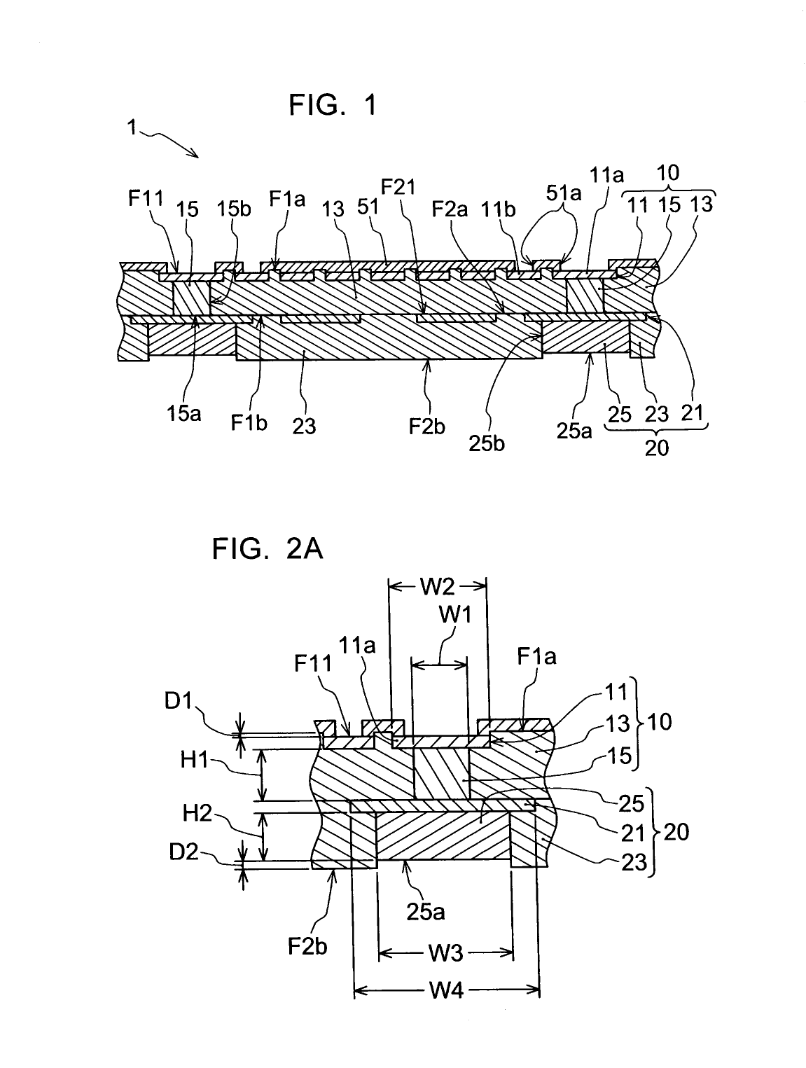

As illustrated in FIG. 1, a multilayer wiring board 1 according to an embodiment of the present invention (hereinafter, the multilayer wiring board is also simply referred to as the wiring board) is formed of multiple wiring bodies (in the example illustrated in FIG. 1, a first wiring body 10 and a second wiring body 20) that are each formed of a laminated body that includes a resin insulating layer and a conductor layer. The first and second wiring bodies (10, 20) are mutually laminated in the same orientation, for example, with their conductor layer sides oriented toward the same direction. The first wiring body 10 includes a resin insulating layer 13 and a conductor layer 11, and forms an outermost layer of the multilayer wiring board 1 on one side. The resin insulating layer 13 has a first surface (F1a) and a second surface (F1b) that is on an opposite side of the first surface (F1a). The conductor layer 11 is embedded in the resin insulating layer 13 on the first surface (F1a) side with only one surface (F11) exposed to the first surface (F1a) of the resin insulating layer 13. The first wiring body 10 is formed such that the first surface (F1a) of the resin insulating layer 13 faces outside of the multilayer wiring board 1. That is, the side on which the conductor layer 11 is embedded faces the outside of the multilayer wiring board 1. The first wiring body 10 further includes a conductor post 15 that is formed from a plating film on a back side of the one surface (F11) of the conductor layer 11. The conductor post 15 penetrates the resin insulating layer 13, and an end surface (15a) of the conductor post 15 is exposed to the second surface (F1b). The second wiring body 20 has a resin insulating layer 23 and a conductor layer 21, and forms an outermost layer of the multilayer wiring board 1 on a side opposite to the first wiring body 10 side. The resin insulating layer 23 has a first surface (F2a) and a second surface (F2b) that is on an opposite side of the first surface (F2a). The conductor layer 21 is embedded in the resin insulating layer 23 on the first surface (F2a) side with only one surface (F21) exposed to the first surface (F2a) of the resin insulating layer 23. The second wiring body 20 further includes a conductor post 25 that is formed from a plating film on a back side of the one surface (F21) of the conductor layer 21. The conductor post 25 penetrates the resin insulating layer 23 so that an end surface (25a) of the conductor post 25 is exposed to the second surface (F2b). Further, the conductor layer 11 of the first wiring body 10 and the conductor post 25 of the second wiring body 20 are electrically connected. In the example illustrated in FIG. 1, via the conductor post 15 of the first wiring body 10 and the conductor layer 21 of the second wiring body 20, the conductor layer 11 of the first wiring body 10 and the conductor post 25 of the second wiring body 20 are connected. A solder resist layer 51 having an opening part (51a) is formed on a surface on the first wiring body 10 side of the multilayer wiring board 1.

In the present embodiment, the one surface (F11) of the conductor layer 11 of the first wiring body 10 is exposed at a recessed position relative to the first surface (F1a) of the resin insulating layer 13 of the first wiring body 10. The end surface (25a) of the conductor post 25 of the second wiring body 20 is recessed from the second surface (F2b) of the resin insulating layer 23 of the second wiring body 20. A recess amount of the end surface (25a) from the second surface (F2b) of the resin insulating layer 23 is greater than a recess amount of the one surface (F11) of the conductor layer 11 from the first surface (F1a) of the resin insulating layer 13. Further, ends on both sides of the conductor post 15 of the first wiring body 10 are respectively directly bonded to adjacent conductor layers (in the example illustrated in FIG. 1, the conductor layer 11 and the conductor layer 21). The conductor layer 21 of the second wiring body 20 is directly bonded to a conductor post of an adjacent wiring body (in the example illustrated in FIG. 1, the conductor post 15 of the first wiring body 10).

As illustrated in FIG. 4, the wiring board of the present embodiment may include at least one wiring body (in the example illustrated in FIG. 4, a third wiring body 30) between the first wiring body 10 and the second wiring body 20. Similar to the first and second wiring bodies (10, 20), the wiring body that is formed between the first wiring body 10 and the second wiring body 20 is formed of a laminated body that includes a resin insulating layer and a conductor layer. Similar to the first and second wiring bodies (10, 20), the wiring body that is formed between the first wiring body 10 and the second wiring body 20 includes a conductor post. Ends of both sides of the conductor post may be respectively directly bonded to adjacent conductor layers.

As an electronic component becomes sophisticated, a large-scale complex electrical circuit is formed in a printed wiring board and, at the time, miniaturization is demanded. Further, the number of conductor pads for connecting to another substrate or the like is likely to increase. Therefore, it is expected that a multilayer structure is necessary. In order to reduce cost, it is preferable to suppress increase in the number of layers by increasing a density of wirings in each layer. On the other hand, for example, although a desired electrical circuit can be obtained using four conductor layers, it may be difficult to ensure an arrangement space for conductor pads for connecting to another substrate. Further, a conductive bonding material such as solder is supplied to the conductor pads for connecting to another substrate. Therefore, it is preferable that such conductor pads be provided on a layer different from a conductor layer on which wiring patterns are formed at a fine pitch.

The multilayer wiring board 1 of the present embodiment includes, on a surface on one side, the first wiring body 10 that includes the conductor layer 11, the conductor post 15 that is formed on the conductor layer 11, and the resin insulating layer 13 that covers a surface of the conductor layer 11 other than the one surface (F11) and a side surface of the conductor post 15. The conductor layer 11 is embedded in the resin insulating layer 13 on the first surface (F1a) side, and the end surface (15a) of the conductor post 15 is exposed to the second surface (F1b). Further, the multilayer wiring board 1 includes, on a surface on a side opposite to the side of the first wiring body 10, the second wiring body 20 that, in the same structure as the first wiring body 10, includes the conductor layer 21, the conductor post 25 and the resin insulating layer 23. The conductor layer 11 of the first wiring body 10 and the conductor post 25 of the second wiring body 20 are electrically connected. The end surface (25a) of the conductor post 25 is exposed to a surface of the multilayer wiring board 1 on a side opposite to the side where the one surface (F11) of the conductor layer 11 is exposed. Therefore, for example, when desired electrical circuits are all formed in the conductor layers (11, 21), the electrical circuits can be connected to another substrate or electronic component via the end surface (25a) of the conductor post 25. Therefore, increase in the number of layers in the multilayer wiring board 1 can be suppressed. The multilayer wiring board 1 can be manufactured at a low cost. In addition, it is likely that problems due to contact of solder or the like to wiring patters in the conductor layers (11, 21) are reduced.

Further, in the multilayer wiring board 1 of the present embodiment, wiring bodies that each include a conductor layer, a resin insulating layer and a conductor post are laminated with their conductor layers oriented toward the same direction. For example, the multilayer wiring board 1 illustrated in FIG. 1 includes the first and second wiring bodies (10, 20). Further, as illustrated in FIG. 4, the multilayer wiring board of the present embodiment may include one or more of any number of wiring bodies between the first wiring body 10 and the second wiring body 20. A wiring body between the first wiring body 10 and the second wiring body 20 may have the same structure as the first and second wiring bodies (10, 20). Therefore, depending on a scale of an electrical circuit to be formed, a multilayer wiring board can be formed to include an arbitrary number of conductor layers. The number of the conductor layers may be an odd number. Therefore, increase in the number of the conductor layers can be suppressed. The number of the layers in the multilayer wiring board can be optimized. As a result, the cost of the multilayer wiring board can be reduced.

In the multilayer wiring board 1 of the present embodiment, the first and second wiring bodies (10, 20) having the structure are laminated. The resin insulating layer 13 that forms a surface-layer portion of the multilayer wiring board 1 on one side and the resin insulating layer 23 that forms a surface-layer portion of the multilayer wiring board 1 on the other side are easily formed of the same material. Even when ambient temperature changes, warpage is unlikely to occur in the multilayer wiring board 1 of the present embodiment.

In the multilayer wiring board of the present embodiment, the conductor posts (15, 25, 35) of the first-third wiring bodies (10, 20, 30) are respectively formed from plating films on the conductor layers (11, 21, 31). Therefore, the conductor posts (15, 25, 35) can be respectively formed of the same materials as the conductor layers (11, 21, 31), such as copper and the like. The conductor posts (15, 25, 35) are respectively directly bonded to the conductor layers when the conductor posts (15, 25, 35) are formed. Therefore, the conductor layer and the conductor post in each of the first-third wiring bodies (10, 20, 30) can be firmly bonded to each other. Further, the conductor post of each wiring body and the conductor layer of another wiring body can also be formed of the same material. The conductor post of each wiring body and the conductor layer of an adjacent another wiring body can be directly bonded to each other, for example, during the formation of the conductor layer of the another wiring body. The two can also be firmly bonded to each other. Therefore, even when a stress occurs during a manufacturing process or during use of the multilayer wiring board, peeling or breaking is unlikely to occur at the interface between the conductor layer and the conductor post. Since the same material can used, a thermal stress occurring at an interface portion is likely to be reduced. As a result, connection reliability of the multilayer wiring board of the present embodiment can be improved.

In the present embodiment, the conductor layer 11 of the first wiring body 10 is embedded in the resin insulating layer 13 on the first surface (F1a) side. Further, the one surface (F11) of the conductor layer 11 is recessed relative to the first surface (F1a) of the resin insulating layer 13. Therefore, for example, when conductor pads for connecting to an electronic component or the like are formed in the conductor layer 11, bonding members supplied to the conductor pads can be prevented from wet-spreading to surrounding areas by walls due to the resin insulating layer 13. Contact between the bonding members is likely to be suppressed. Since the concern about wet spreading of the bonding members is reduced, the bonding members in originally required amounts can be supplied to the conductor pads. As a result, bonding failure between the multilayer wiring board of the present embodiment and an electronic component or the like can be reduced.

Further, in the present embodiment, the end surface (25a) of the conductor post 25 is recessed relative the second surface (F2b) of the resin insulating layer 23 of the second wiring body 20. Therefore, for example, a bonding member such as solder can be supplied to the end surface (25a) without wet-spreading to the side surface of the conductor post 25 or the like. Further, when bonding members are melted, the resin insulating layer 23 between conductor posts 25 can become walls that prevent flow of the bonding members. Therefore, contact between bonding members of adjacent conductor posts 25 can be prevented. Electrical short circuiting between the conductor posts 25 can be prevented. Further, since, as described above, the concern about the contact between the bonding members is reduced, a bonding member in an originally required amount can be supplied to the end surface (25a) of a conductor post 25. As a result, occurrence of a bonding failure between the multilayer wiring board of the present embodiment and another wiring board or the like can be reduced.

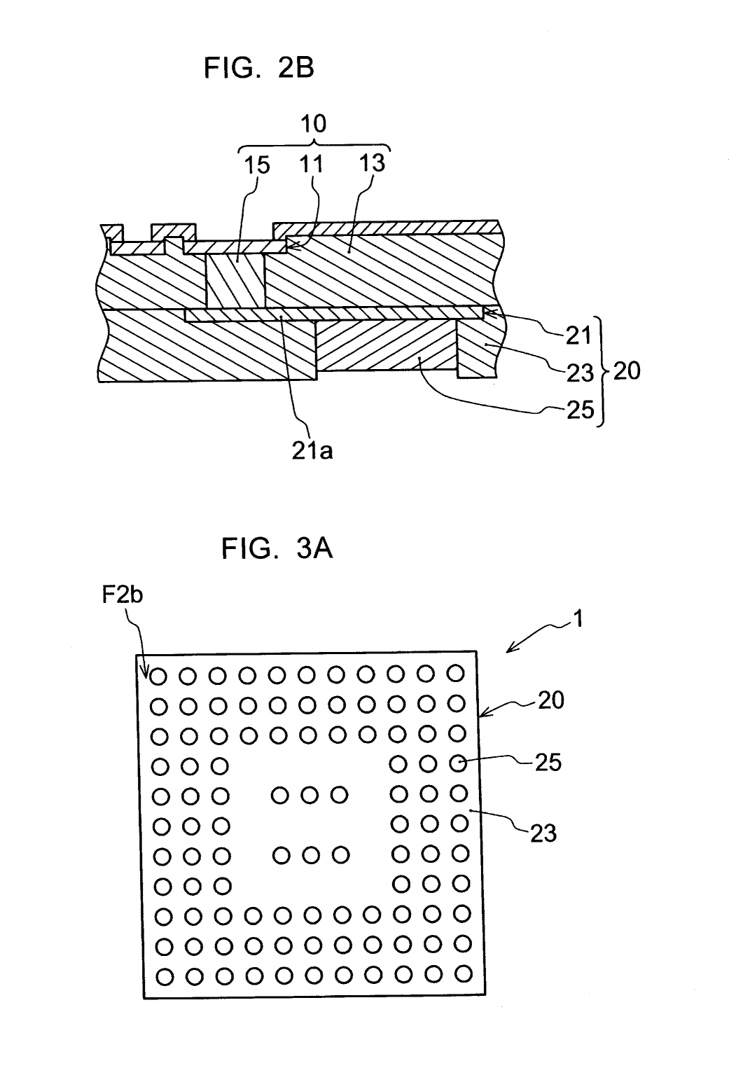

In the present embodiment, the recess amount of the end surface (25a) of the conductor post 25 of the second wiring body 20 from the second surface (F2b) of the resin insulating layer 23 is greater than the recess amount of the one surface (F11) of the conductor layer 11 from the first surface (F1a) of the resin insulating layer 13 of the first wiring body 10. That is, a distance (D2) (see FIG. 2A) from the second surface (F2b) of the resin insulating layer 23 to the end surface (25a) of the conductor post 25 is greater than a distance (D1) (see FIG. 2A) from the first surface (F1a) of the resin insulating layer 13 to the one surface (F11) of the conductor layer 11. For example, a semiconductor element (not illustrated in the drawings) and connection pads provided in the conductor layer 11 can be connected by wire bonding or the like. In this case, on a connection surface of the conductor layer 11, that is, on the one surface (F11), a bonding layer (not illustrated in the drawings) can be formed from a material suitable for bonding using a plating method or the like. During the formation of the bonding layer, when the end surface (25a) of the conductor post 25 is not masked, a plating film having a thickness substantially the same as that on the one surface (F11) of the conductor layer 11 is also formed on the end surface (25a). In the present embodiment, the recess of the end surface (25a) of the conductor post 25 is larger than the recess of the one surface (F11) of the conductor layer 11. Therefore, even when a bonding layer thick enough to fill the recess relative to the first surface (F1a) of the resin insulating layer 13 is formed on the one surface (F11) of the conductor layer 11, the recess of the end surface (25a) is unlikely to be filled by the plating film. A space for supplying solder or the like can remain. Therefore, the above-described bonding layer can be formed without masking the end surface (25a) of the conductor post 25.

Further, in the above-described printed wiring board of Patent Document 1, the conductor circuit is formed on the surface of the insulating substrate. Therefore, along with advances in forming wiring patterns at a fine pitch, when a contact area between a conductor pad or the like (for connecting to an electronic component) and the insulating substrate is reduced, bonding strength between the insulating substrate and the conductor pad is expected to decrease. Therefore, when a stress due to a difference in thermal expansion coefficient between the electronic component and the conductor pad acts on the conductor pad, the conductor pad is likely to be easily peeled off from the insulating substrate.

The conductor layer 11 of the first wiring body 10 of the wiring board 1 of the present embodiment is embedded in the resin insulating layer 13 on the first surface (F1a) side (the first surface (F1a) facing outside of the wiring board 1) with only the one surface (F11) exposed. The conductor layer 11 is bonded to the resin insulating layer 13 not only at a surface on a back side of the exposed surface (F11) but also at a side surface of the conductor layer 11. Therefore, even when a conductor pad for connecting to an electronic component or the like is provided to have a small area, peeling or the like of the conductor pad is unlikely to occur. As a result, reliability of the multilayer wiring board can be improved. Conductor pads for connecting to an electronic component can be formed at a fine pitch. Therefore, the one surface (F11) of the conductor layer 11 can be a preferred mounting surface for connecting to an electronic component such as a semiconductor element on which a large number of electrodes are provided at a fine pitch.

Elements that form the wiring board 1 of the embodiment illustrated in FIG. 1 are sequentially described below. The conductor layer 11 and the conductor layer 21, the resin insulating layer 13 and the resin insulating layer 23, and the conductor post 15 and the conductor post 25, respectively have the same structures. Common matters between the first wiring body 10 and the second wiring body 20 are collectively described by listing the reference numeral symbols with respect to the wiring bodies.

The conductor layer 11 of the first wiring body 10 is patterned to have desired mounting pads and wiring patterns depending on an electrical circuit formed in the wiring board 1 and depending on an electronic component or the like to be mounted. In the example illustrated in FIG. 1, conductor patterns such as a first pattern (11a) for connecting to the conductor post 15 and a second pattern (11b) for connecting to an electrode or the like of a semiconductor element (not illustrated in the drawings) are formed in the conductor layer 11. The conductor layer 11 is preferably formed by electrolytic plating only without using etching. In this case, the wiring patterns can be formed at a fine pitch. (Minimum width)/(minimum spacing) (line and space: L/S) of the wiring patterns formed in the conductor layer 11 is (15 μm)/(15 μm), for example.

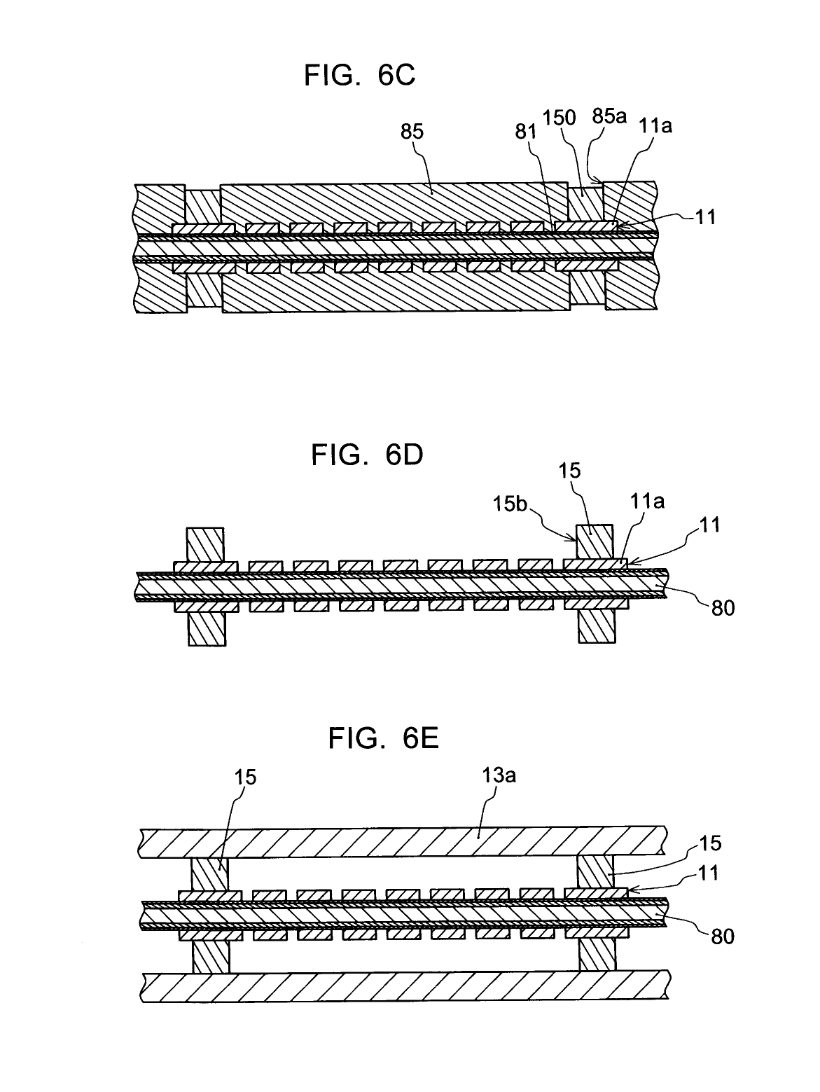

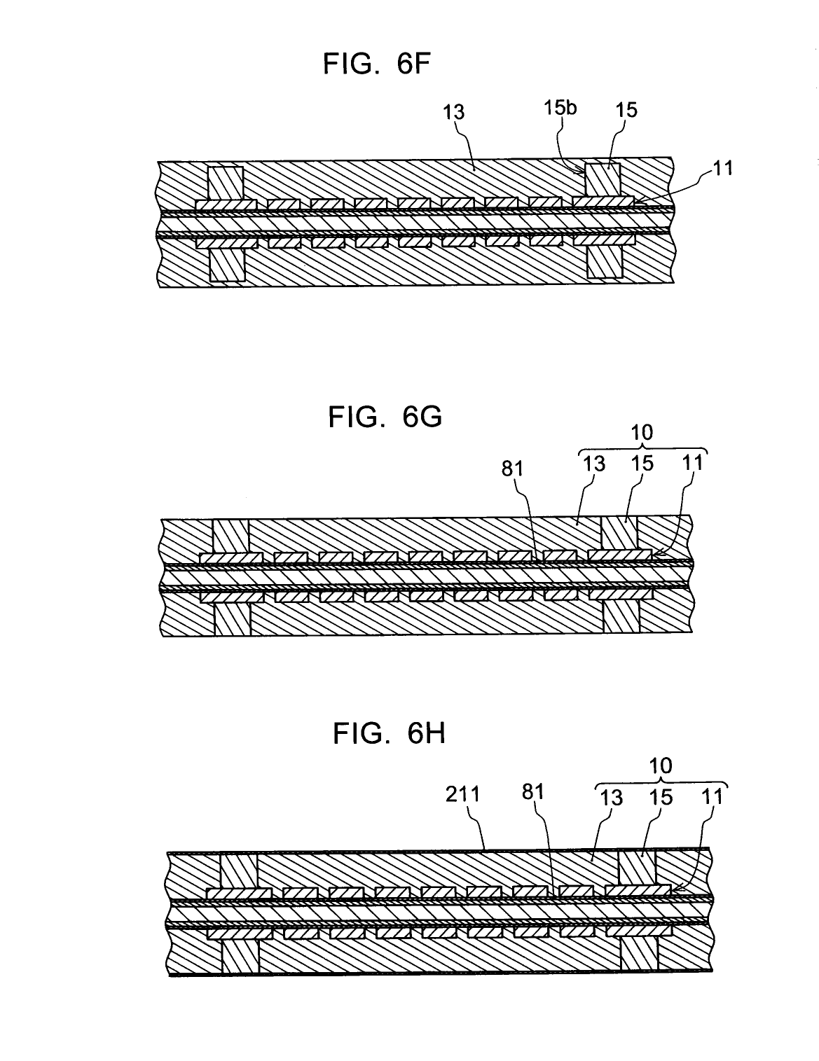

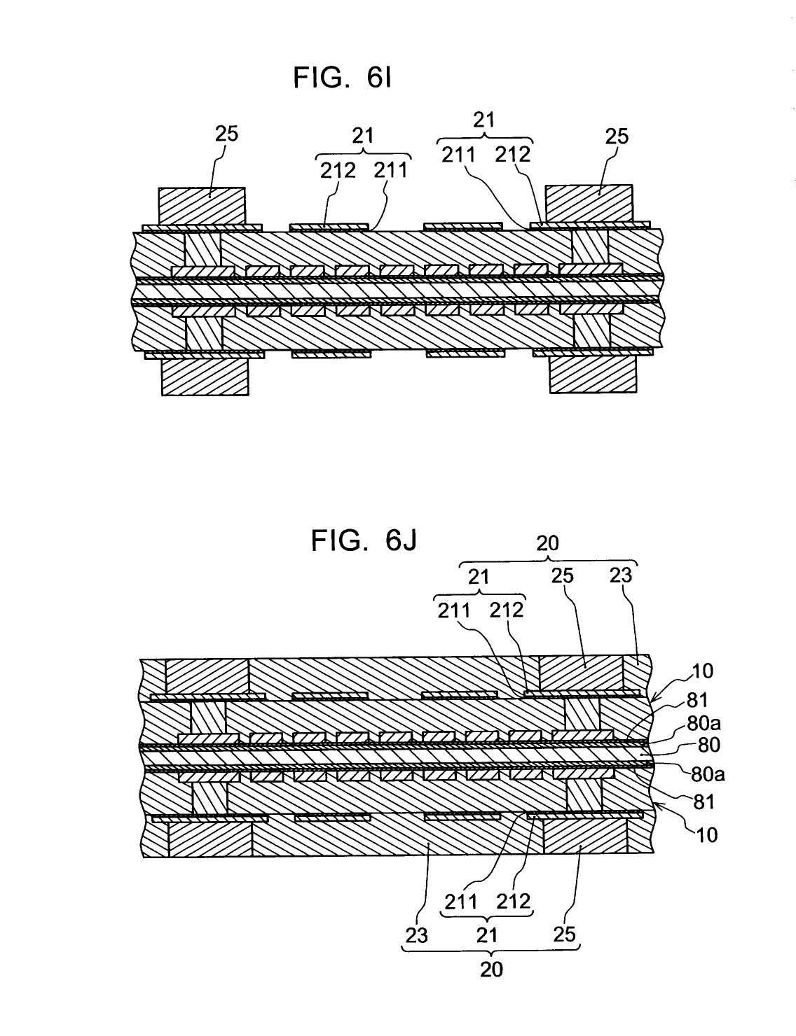

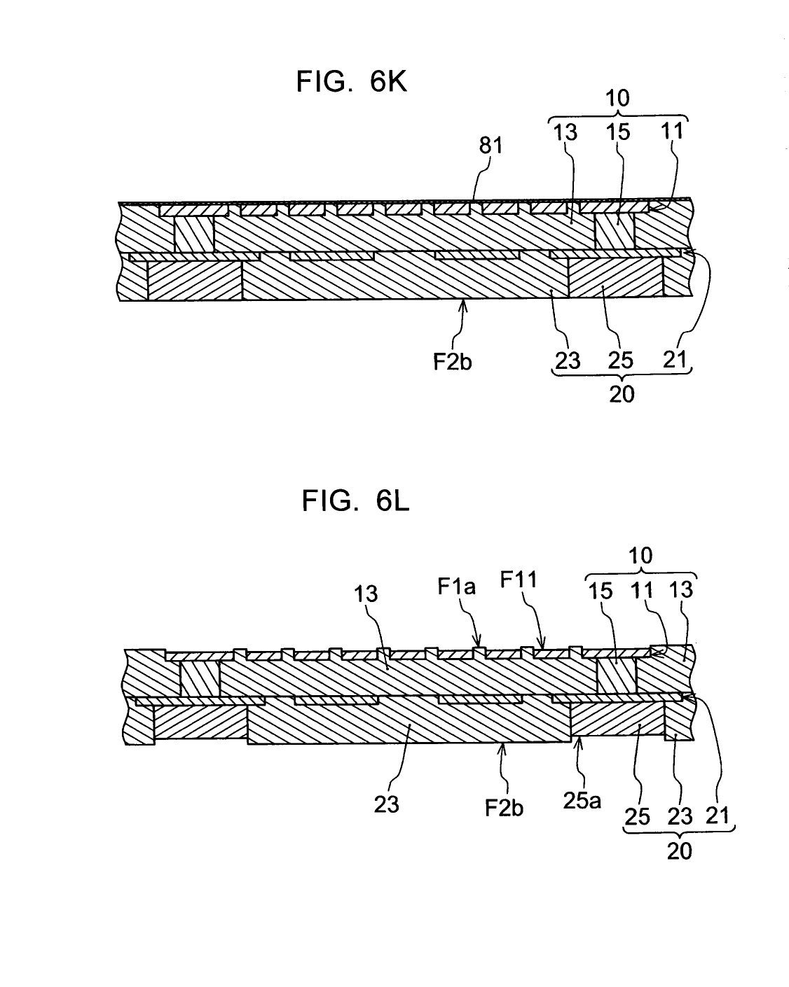

The conductor layer 21 of the second wiring body 20 is embedded in the resin insulating layer 23 on the first surface (F2a) side. The conductor layer 21 may be formed to include multiple layers that are each formed of a conductive material (in FIG. 1, the conductor layer 21 is illustrated as having a single-layer structure by omitting structural details). For example, as illustrated in FIG. 6I, the conductor layer 21 may have a two-layer structure that includes a metal coating 211 that is provided on a surface of the resin insulating layer 13 and a plating film 212 that is formed on the metal coating 211. The metal coating 211 may be formed to have a thickness of about 0.05-1 μm, and the plating film 212 may be formed to have a thickness of about 5-25 μm. The conductor layer 21 is formed to have a thickness of, for example, about 5-25 μm. The conductor layer 21 may also have a three-layer structure that has a metal foil (not illustrated in the drawings) between the metal coating 211 and the resin insulating layer 13 illustrated in FIG. 6I. When the conductor layer 21 is formed to have the structure that has the metal foil (not illustrated in the drawings), strong adhesion between the conductor layer 21 and the resin insulating layer 13 can be obtained. The structure having the metal foil is particularly advantageous when a material having relatively low adhesion to the metal coating 211 formed by electroless plating or the like is used for the resin insulating layer 13. On the other hand, when the resin insulating layer 13 has sufficient adhesion to the metal coating 211, it is preferable that the conductor layer 21 be formed to have a two-layer structure. Since the metal foil is not required, cost of the multilayer wiring board 1 can be reduced.

The resin insulating layer 13 of the first wiring body 10 covers a side surface of the conductor layer 11 and an exposed portion of a formation surface of the conductor post 15 such that the conductor layer 11 is embedded on the first surface (F1a) side. The resin insulating layer 13 further covers a side surface (15b) of the conductor post 15. The resin insulating layer 23 of the second wiring body 20 covers a side surface of the conductor layer 21 and an exposed portion of a formation surface of the conductor post 25 such that the conductor layer 21 is embedded on the first surface (F2a) side. The resin insulating layer 23 further covers a side surface (25b) of the conductor post 25.

A material of the resin insulating layers (13, 23) is formed from a resin composition that contains a reinforcing material such as glass fiber, or, preferably, is formed from a resin composition that does not contain a reinforcing material. As the resin composition, an epoxy resin is preferably used. More preferably, an epoxy resin containing 30-80% by weight of an inorganic filler such as silica is used. Further, the material of the resin insulating layers (13, 23) may be a resin composition suitable for being supplied in sheet-like or film-like form when the wiring board 1 is manufactured. Or, the material of the resin insulating layers (13, 23) may be a resin material for mold-molding suitable for a case where the resin insulating layers (13, 23) are formed by mold-molding. Preferably, a resin material having a thermal expansion coefficient of 6-30 ppm/° C., an elastic modulus of 5-25 GPa and a glass transition temperature of 100-220° C. is used for the resin insulating layers (13, 23). When a resin material having such properties is used for the material of the resin insulating layers (13, 23), for example, an excessive stress is unlikely to occur at an interface with the conductor layers (11, 21). An excessive stress is unlikely to occur at a connecting part that connects to a semiconductor element or the like (not illustrated in the drawings) that is mounted on the conductor layer 11. Breaking of the connecting part or peeling between the conductor layers and resin insulating layers (13, 23) is unlikely to occur. However, the properties of the resin insulating layers (13, 23) are not limited to these. A resin material having properties such as a thermal expansion coefficient and an elastic modulus outside the above-described ranges can be used. The resin insulating layer 13 and the resin insulating layer 23 may be formed from the same resin material. For example, when the conductor post 15 and the conductor post 25 are formed of substantially the same material and have substantially the same structure and the conductor layer 11 and the conductor layer 21 are formed of substantially the same material and have substantially the same structure, there are cases where it is preferable that the same resin material be used. However, for example, depending on materials, formation densities, heights or the like of conductor posts 15 and conductor posts 25, optimal resins may be respectively selected. The resin insulating layer 13 and the resin insulating layer 23 may also be respectively formed from mutually different resin materials.

The conductor post 15 of the first wiring body 10 is formed from a plating film on a portion of a surface on an opposite side of the one surface (F11) of the conductor layer 11. Similarly, the conductor post 25 of the second wiring body 20 is formed from a plating film on a portion of a surface on an opposite side of the one surface (F21) of the conductor layer 21. As illustrated in FIG. 1, the conductor posts (15, 25) are respectively formed in a circular cylindrical or circular truncated cone shape on portions of wiring patterns of the conductor layers (11, 21). A planar shape of each of the conductor posts (15, 25) is not limited to a circular shape. Therefore, the conductor posts (15, 25) may also each have a shape of a columnar body other than a circular cylinder or a shape of a trapezoid body other than a circular truncated cone. In the present embodiment, the conductor post 15 extends from the surface of the conductor layer 11 toward the second surface (F1b) of the resin insulating layer 13. The end surface (15a) of the conductor post 15 is exposed from the resin insulating layer 13 on the second surface (F1b) side of the resin insulating layer 13. Similarly, the conductor post 25 extends from the surface of the conductor layer 21 toward the second surface (F2b) of the resin insulating layer 23. The end surface (25a) of the conductor post 25 is exposed from the resin insulating layer 23 on the second surface (F2b) side of the resin insulating layer 23. The conductor posts (15, 25) electrically connect between, for example, predetermined electrodes of a semiconductor element (not illustrated in the drawings) that is connected to a conductor pattern in the conductor layer 11 and another printed wiring board or the like (not illustrated in the drawings). Conductor posts 15 and conductor posts 25 may be provided in a number corresponding to the number of the electrodes of the semiconductor element (not illustrated in the drawings).

The conductor posts (15, 25) may also have oval, square, rectangular or rhombic planar shapes. When the conductor posts (15, 25) are formed by electrolytic plating, the conductor posts (15, 25) can be formed to have any planar shapes by forming openings in resist films in desired shapes during plating.

Further, side surfaces (15b, 25b) of the conductor posts (15, 25) may be subjected to a roughening treatment. By roughening the side surfaces (15b, 25b), a so-called anchor effect is achieved, and adhesion between the conductor posts (15, 25) and the resin insulating layers (13, 23) is improved. Further, the side surfaces of the conductor layers (11, 21) and the exposed portions of the formation surfaces of the conductor posts (15, 25) of the conductor layers (11, 21) may be similarly subjected to a roughening treatment. In this case, adhesion between the conductor layers (11, 21) and the resin insulating layers (13, 23) can be improved.

An example of preferred dimensions of the conductor post 15 of the first wiring body 10 and the conductor post 25 of the second wiring body 20 and their peripheral parts is described below with reference to FIG. 2A. A height (H1) of the conductor post 15 of the first wiring body 10 is set to be a height that allows a desired insulation property to be maintained between the conductor layer 11 of the first wiring body 10 and the conductor layer 21 of the second wiring body 20. For example, the height (H1) of the conductor post 15 is 50-150 μm. The height (H1) of the conductor post 15 is not limited to this. A height (H2) of the conductor post 25 of the second wiring body 20 is not particularly limited as long as it is a height that allows a descried insulation property to be maintained between the conductor layer 21 of the second wiring body 20 and, for example, a motherboard (not illustrated in the drawings) or the like. For example, the height (H2) of the conductor post 25 is 50-150 μm. When the conductor posts (15, 25) are formed to have such heights, a stress due to a difference in thermal expansion coefficient or the like between the first wiring body 10, the second wiring body 20 and, for example, a motherboard can be relaxed. In addition, a total height including the motherboard or the like does not become too high.

A width (W1) of the conductor post 15 of the first wiring body 10, for example, is 80-300 μm and preferably 120 μm. The width of the conductor post 15 means a diameter when the conductor post has a circular planar shape, a length of a major axis when the conductor post has an oval planar shape, or a length of a longest diagonal line when the conductor post has a polygonal planar shape (the same also applies to a width of the conductor post 25). A width (W2) of a conductor land (first pattern (11a)) of the conductor layer 11 on which the conductor post 15 is formed, for example, is 90-350 μm and preferably 170 μm. The width of the conductor land of the conductor layer 11 means a diameter when the conductor land has a circular planar shape, a length of a major axis when the conductor land has an oval planar shape, or a length of a longest diagonal line when the conductor land has a polygonal planar shape (the same also applies to a width of a conductor land of the conductor layer 21). A width (W3) of the conductor post 25 of the second wiring body 20, for example, is 80-300 μm and preferably 230 μm. A width (W4) of a conductor land of the conductor layer 21 on which the conductor post 25 is formed, for example, is 90-350 μm and preferably 280 μm.

Further, the distance (D1) from the first surface (F1a) of the resin insulating layer 13 of the first wiring body 10 to the one surface (F11) of the conductor layer 11 is, for example, 0.1-5 μm. When the distance (D1) is set to be such a length, as described above, wet spreading of a bonding member such as solder that is supplied to the one surface (F11) can be prevented. Further, as will be described later, a time period of etching or the like for causing the one surface (F11) of the conductor layer 11 to be recessed relative to the first surface (F1a) of the resin insulating layer 13 does not become too long. The distance (D2) from the second surface (F2b) of the resin insulating layer 23 of the second wiring body 20 to the end surface (25a) of the conductor post 25 is, for example, 3-10 μm. When the distance (D2) is set to be such a length, a too long time period is not required for causing a front end portion of the conductor post 25 to be recessed relative to the second surface (F2b) of the resin insulating layer 23 by etching or the like. Further, a sufficient space for supplying a bonding member such as solder on the end surface (25a) is ensured. These dimensions may be respectively above or below the above-described ranges. FIG. 1 and the like illustrate an example in which the width of the conductor post 15 of the first wiring body 10 is smaller than the width of the conductor post 25 of the second wiring body 20. The relation between the sizes of the two is not limited to this. For example, it is also possible that the width of the conductor post 15 is greater than the width of the conductor post 25.

In the wiring board 1 of the present embodiment, a surface protection film (not illustrated in the drawings) may be formed on the one surface (F11) of the conductor layer 11 of the first wiring body 10 and on the exposed surface of the end surface (25a) of the conductor post 25 of the second wiring body 20. The surface protection film, in addition to being a protective film against corrosion such as oxidation, may also be a film that is formed in order to achieve good bondability to, for example, solder, a bonding wire, and the like. The surface protection film may be formed on both of the one surface (F11) of the conductor layer 11 and the end surface (25a) of the conductor post 25 or may be formed on only one of the two. Further, surface protection films of different materials may be respectively formed on the two.

Further, as described above, a bonding member in a layered or bump-like shape or in any other shape may be supplied to the end surface (25a) of the conductor post 25 that is recessed relative to the second surface (F2b) of the resin insulating layer 23 of the second wiring body 20.

In the example illustrated in FIGS. 1 and 2A, the conductor post 15 of the first wiring body 10 and the conductor post 25 of the second wiring body 20 are formed such that they are stacked in a thickness direction of the wiring board 1 via the conductor layer 21 of the second wiring body 20. The conductor layer 11 of the first wiring body 10 and the conductor post 25 of the second wiring body 20 are connected by the conductor post 15. The conductor post 15 is formed at a position where a projection image of the conductor post 15 on a plane parallel to the wiring board 1 (hereinafter, a projection image on a plane parallel to the wiring board 1 is also simply referred to as a projection image) overlaps with a projection image of the conductor post 25. An example of a plane parallel to the wiring board 1 is the first surface (F1a) of the resin insulating layer 13. As illustrated in FIGS. 1 and 2A, when the conductor post 15 and the conductor post 25 are formed such that they are stacked with their central axes aligned, it is possible that, for example, a conductor pattern that connects the conductor post 15 and the conductor post 25 in the conductor layer 21 is not required. Further, also in a case where the conductor post 15 and the conductor post 25 are formed such that their projection images at least partially overlap each other, similarly, it is possible that a conductor pattern for connection is not required. A planar size of the wiring board 1 can be reduced. When conductor posts (15, 25) are formed, all of them may be formed to be stacked as illustrated in FIG. 1. The wiring board 1 can be further reduced in size. Further, even when only some of the conductor posts (15, 25) are formed as illustrated in FIG. 1, the wiring board 1 can also be reduced in size.

However, it is also possible that all of the conductor posts 15 of the first wiring body 10 and the conductor posts 25 of the second wiring body 20 are formed at positions where their projection images do not overlap each other. An example of such a positional relation between the conductor post 15 and the conductor post 25 is illustrated in FIG. 2B. In the example illustrated in FIG. 2B, the conductor post 15 of the first wiring body 10 and the conductor post 25 of the second wiring body 20 are formed at positions where the two do not overlap at all in a plan view. The two are connected by a connection pattern (21a) that is formed in the conductor layer 21. When the two are formed at positions where they do not overlap in a plan view as described above, the conductor post 25 of the second wiring body 20 is formed on the surface of the conductor layer 21 that is not on the conductor post 15 but on the flat resin insulating layer 13. As a result, the conductor post 25 that is firmly bonded to the conductor layer 21 and has high connection reliability can be obtained.

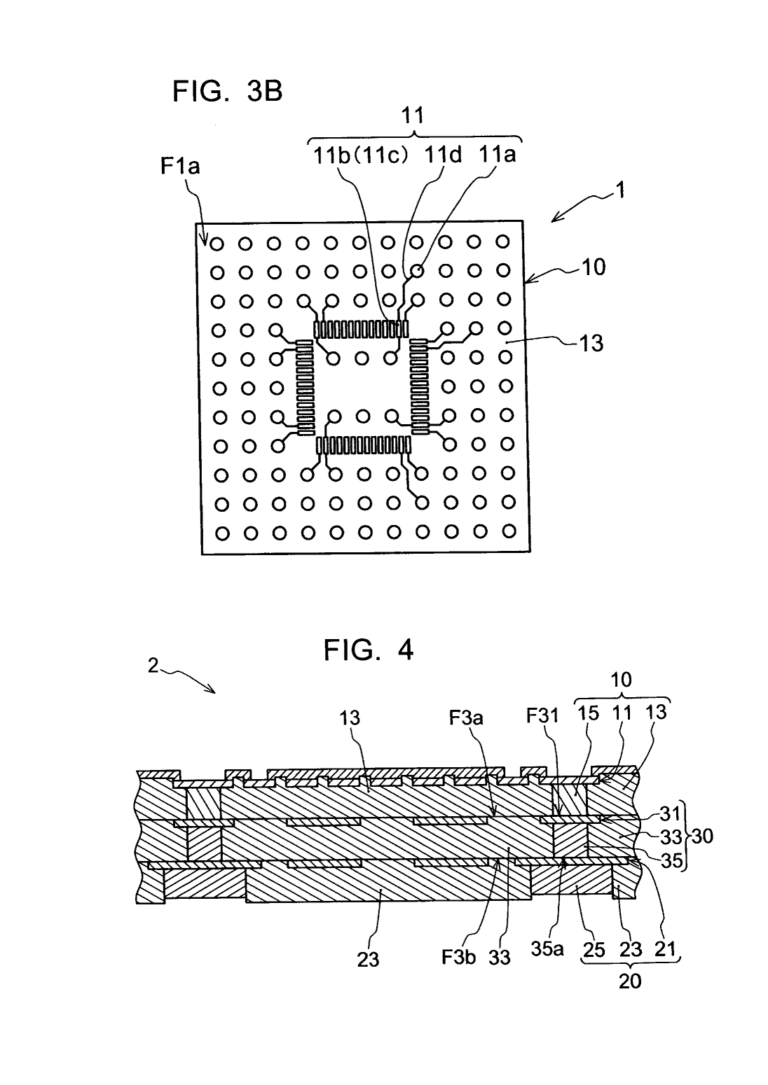

The conductor posts 15 of the first wiring body 10 and the conductor posts 25 of the second wiring body 20 are respectively provided at arbitrary positions on the conductor layers (11, 21) depending on an electrical circuit formed in the wiring board 1 or an electronic component to be mounted. FIG. 3A illustrates an exemplary array of the conductor posts 25 of the second wiring body 20 of the wiring board 1 of the present embodiment in a state viewed from the second surface (F2b) side of the resin insulating layer 23. As illustrated in FIG. 3A, multiple conductor posts 25 may be provided in a dot pattern in a portion of or the entire area of the wiring board 1 along the surface of the conductor layer 21 (see FIG. 1) of the second wiring body 20. Or, the conductor posts 25 may be arrayed in one row or in multiple rows in a go-around manner along an outer periphery of the wiring board 1. Further, the conductor posts 25 may also be arrayed at a constant interval or may be arrayed by appropriately varying the intervals. The conductor posts 25 may be provided at arbitrary positions. The conductor posts 15 of the first wiring body 10 also may be provided in a dot pattern in a portion of or the entire area along the surface of the conductor layer 11 of the first wiring body 10. Or, the conductor posts 15 may be provided in a go-around manner along the outer periphery of the wiring board 1. An arbitrary number of conductor posts 15 may be provided at arbitrary positions at arbitrary intervals.

FIG. 3B illustrates an example of wiring patterns of the conductor layer 11 of the first wiring body 10 of the wiring board 1 illustrated in FIG. 3A in a state viewed from the first surface (F1a) side of the resin insulating layer 13. The first and second patterns (11a, 11b) and a wiring pattern (11d) that connects between the first pattern (11a) and the second pattern (11b) are formed in the conductor layer 11. The conductor posts 15 (see FIG. 1) are connected to a surface of the first pattern (11a) on an opposite side of a surface illustrated in FIG. 3B. The conductor posts 15 are connected to the conductor posts 25 illustrated in FIG. 3A via the conductor layer 21 (see FIG. 1) of the second wiring body 20. The conductor posts 25 illustrated in FIG. 3A and the first patterns (11a) illustrated in FIG. 3B may be arrayed at the same positions or at different positions on a plane. That is, a conductor post 15 and a conductor post 25 may be formed to be stacked as illustrated in FIG. 2A. Or, a conductor post 15 and a conductor post 25 may be formed at different positions on a plane as illustrated in FIG. 2B.

In the example illustrated in FIG. 3B, the second patterns (11b) are connection pads (11c) to which a semiconductor element (not illustrated in the drawings) is connected. The connection pads (11c) are electrically connected to electrodes of an IC chip or the like via solder bumps or the like. FIG. 3B illustrates an example of the connection pads (11c) that are connected to a semiconductor element of which electrodes are arrayed on four sides of a rectangular outer shape. In the example illustrated in FIGS. 3A and 3B, the conductor posts 25 are not provided at positions that are directly on the back of the connection pads (11c). In this case, surface flatness of the connection pads (11c) can be increased and good connection to a semiconductor element or the like can be obtained. However, the conductor posts 25 may also be provided at positions that are directly on the back of the connection pads (11c).

In the example illustrated in FIG. 3B, a connection pad (11c) (second pattern (11b)) and a first pattern (11a) that is formed in a surrounding area of the connection pad (11c) is connected by a wiring pattern (11d). As a result, the electrodes of the semiconductor element (not illustrated in the drawings) that are connected to the connection pads (11c) are electrically connected to another printed wiring board such as a motherboard via the conductor posts 15 of the first wiring body 10 and the conductor layer 21 and the conductor posts 25 of the second wiring body 20. FIGS. 3A and 3B illustrate an example of array of the conductor posts 25 and an example of the conductor patterns that are formed in the conductor layer 11. An arbitrary number of conductor posts 25 and an arbitrary number of conductor patterns in the conductor layer 11 may be formed at any positions and in any forms.

In the example illustrated in FIG. 1, the opening parts (51a) that expose the first patterns (11a) and the second patterns (11b) are provided in the solder resist layer 51. Surrounding areas of the first and second patterns (11a, 11b) are covered by the solder resist layer 51. The opening parts (51a) may be provided in sizes that allow the entire surfaces of the first and second patterns (11a, 11b) to be exposed. Further, the opening parts may be provided in accordance with the positions and the number of the conductor patterns that are formed in the conductor layer 11. Further, although not illustrated in the drawings, a solder resist layer may be formed also on the second surface (F2b) of the resin insulating layer 23 of the second wiring body 20. In this case, opening parts that expose the end surfaces (25a) of the conductor posts 25 are formed in the solder resist on the second surface (F2b).

The multilayer wiring board of the present embodiment may further include, between the first wiring body 10 and the second wiring body 20, one or more wiring bodies that are each formed of a laminated body that includes a resin insulating layer and a conductor layer. FIG. 4 illustrates a multilayer wiring board 2 as an example of such another embodiment. The multilayer wiring board 2 has a third wiring body 30 between the first wiring body 10 and the second wiring body 20, the third wiring body 30 having the same structure as the first and second wiring bodies (10, 20). In the following description about the multilayer wiring board 2, a structural element that is the same as in the multilayer wiring board 1 illustrated in FIG. 1 and the like is indicated using the same reference numeral symbol and detailed description thereof is omitted.

As compared to the multilayer wiring board 1 illustrated in FIG. 1, the multilayer wiring board 2 illustrated in FIG. 4 FIG. 1 is different in that the third wiring body 30 is formed between the first wiring body 10 and the second wiring body 20. Similar to the first and second wiring bodies (10, 20), the third wiring body 30 is formed by laminating a resin insulating layer 33 and a conductor layer 31. The resin insulating layer 33 has a first surface (F3a) and a second surface (F3b) that is on an opposite side of the first surface (F3a). The conductor layer 31 is embedded in the resin insulating layer 33 on the first surface (F3a) side with only one surface (F31) being exposed to the first surface (F3a) of the resin insulating layer 33. The third wiring body 30 further includes a conductor post 35 that is formed from a plating film on a back side of the one surface (F31) of the conductor layer 31. The conductor post 35 penetrates the resin insulating layer 33, and an end surface (35a) of the conductor post 35 is exposed to the second surface (F3b). In the example illustrated in FIG. 4, ends on both sides of the conductor post 35 are respectively directly bonded to the adjacent conductor layer 31 and the adjacent conductor layer 21 of the second wiring body 20. The ends on both sides of the conductor post 15 of the first wiring body 10 are respectively directly bonded to the adjacent conductor layer 11 and the adjacent conductor layer 31. The conductor layer 11 of the first wiring body 10 and the conductor post 25 of the second wiring body 20 are electrically connected via the conductor post 15 of the first wiring body 10, the conductor layer 31 and the conductor post 35 of the third wiring body 30, and the conductor layer 21 of the second wiring body 20.

As in the multilayer wiring board 2 illustrated in FIG. 4, by including more wiring bodies, without increasing a planar size, a larger-scaled and more complex electrical circuit can be formed in the multilayer wiring board 2. In the example illustrated in FIG. 4, the multilayer wiring board 2 can be connected to another printed wiring board or the like via the conductor post 25 of the second wiring body 20. Therefore, when a desired electrical circuit is formed using the conductor layers (11, 21, 31) in the first, second and third wiring bodies (10, 20, 30), it is possible that it is not necessary to further include a conductor layer for providing connection pads.

The wiring board of the present embodiment may include, between the first wiring body 10 and the second wiring body 20, two or more wiring bodies that are each formed of a laminated body that includes a conductor layer and a resin insulating layer. As a result, an even larger-scaled electrical circuit can be formed in the multilayer wiring board of the same planar size. The conductor layer, the resin insulating layer and the conductor post that form a wiring body provided between the first wiring body 10 and the second wiring body 20 may respectively be formed of the same materials and have the same structures as the conductor layer 21, the resin insulating layer 23 and the conductor post 25 that form the above-described second wiring body 20. The resin insulating layer and the conductor post that form a wiring body provided between the first wiring body 10 and the second wiring body 20 may respectively be formed of the same materials and have the same structures as the resin insulating layer 13 and the conductor post 15 that form the above-described first wiring body 10.

In the multilayer wiring board 2 illustrated in FIG. 4, the conductor post 35 of the third wiring body 30 is formed to be stacked on the conductor post 25 via the conductor layer 21 of the second wiring body 20. The conductor post 15 of the first wiring body 10 is formed to be stacked on the conductor post 35 via the conductor layer 31 of the third wiring body 30. The conductor posts (15, 25, 35) of the first, second and third wiring bodies (10, 20, 30) are stacked with their central axes aligned. By the stacked conductor post 15 and conductor post 35, the conductor layer 11 of the first wiring body 10 and the conductor post 25 of the second wiring body 20 are connected. In this way, when the conductor posts of the wiring bodies are formed to be stacked with their central axes aligned, the planar size of the multilayer wiring board 2 of the present embodiment can be reduced. When conductor posts are formed in each of the wiring bodies, it is possible that only some of the conductor posts are formed to be stacked. Or, it is also possible that all of the conductor posts are formed to be stacked. The size of the multilayer wiring board 2 can be further reduced. It is also possible that the conductor posts (15, 25, 35) are formed with their central axes shifted from each other. In this case, the conductor post 15 and the conductor post 35 may be stacked at positions where the projection images of the conductor post 15 and the conductor post 35 at least partially overlap with the projection image of the conductor post 25. Also in this case, the planar size of the multilayer wiring board 2 can be reduced.

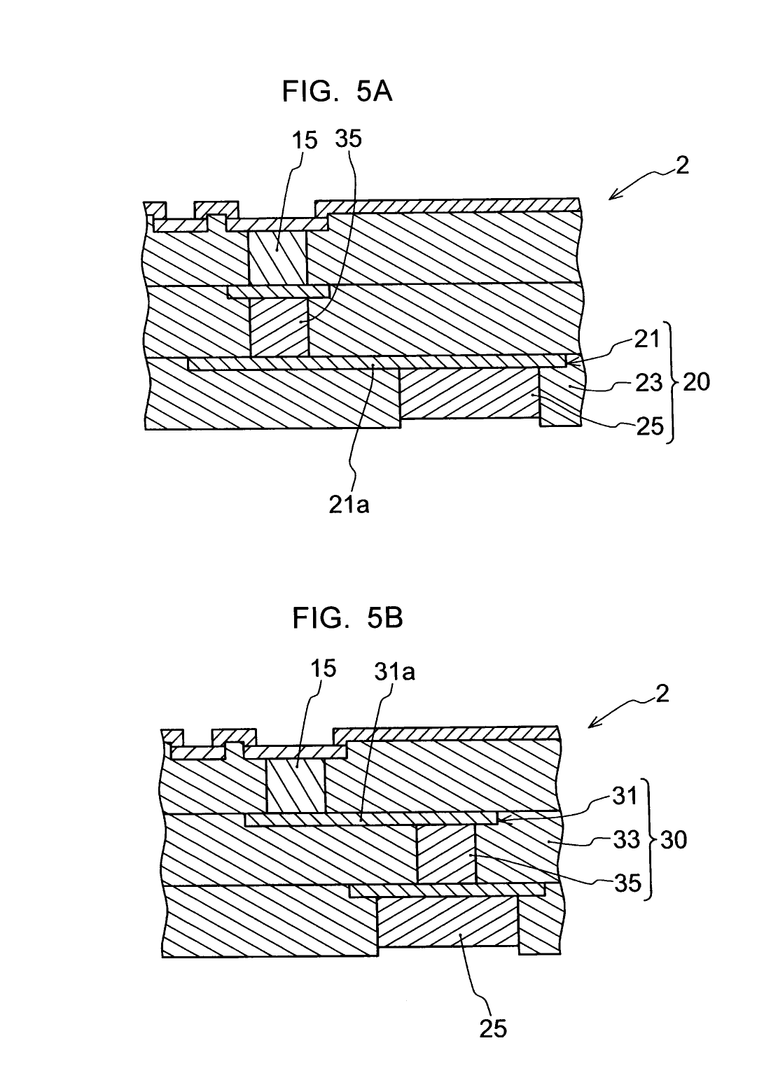

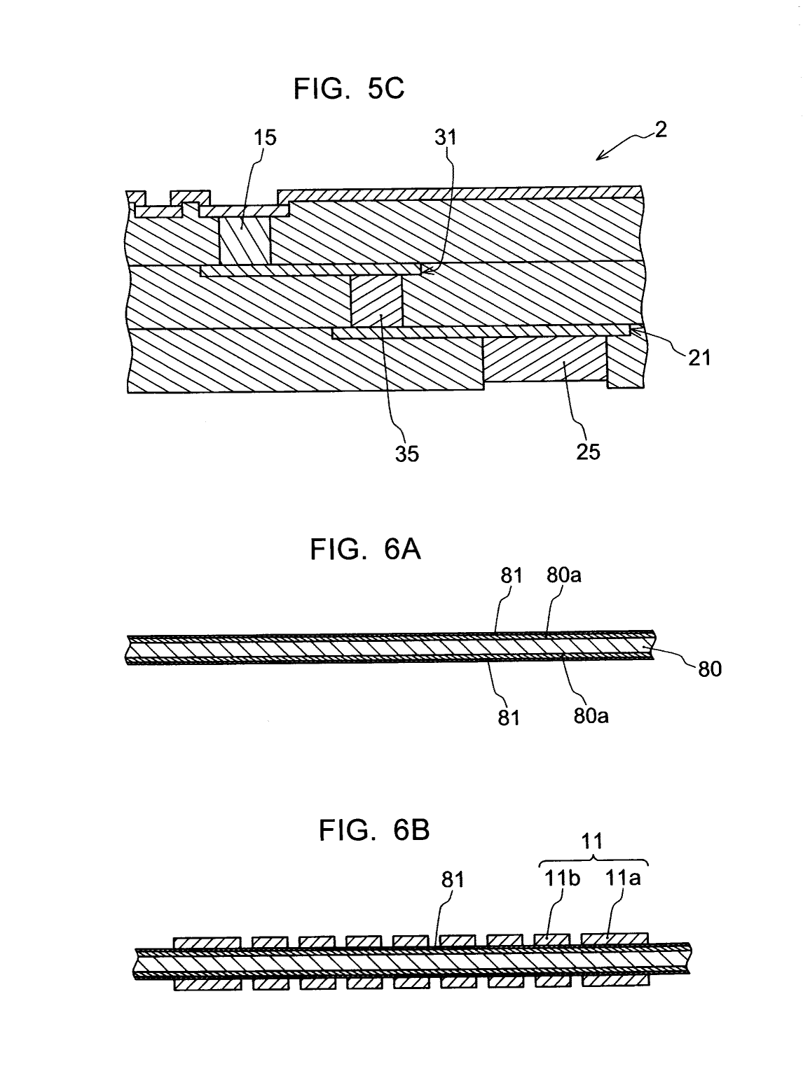

The conductor posts (15, 25, 35) may also be formed at different positions in a plan view. For example, the conductor posts (15, 25, 35) may also be formed such that their projection images do not overlap each other. As illustrated in FIG. 5A, it is also possible that the conductor post 15 and the conductor post 35 are formed to be stacked along the same central axis, and the conductor post 25 is formed at a position different in a plan view from that of the conductor post 35. In this case, the conductor post 25 and the conductor post 35 can be connected by the connection pattern (21a) of the conductor layer 21 of the second wiring body 20. As illustrated in FIG. 5B, it is also possible that the conductor post 35 and the conductor post 25 are formed to be stacked along the same central axis, and the conductor post 15 is formed at a position different from that of the conductor post 35. The conductor post 15 can be connected to the conductor post 35 by a connection pattern (31a) in the conductor layer 31 of the third wiring body 30. As illustrated in FIG. 5C, it is also possible that the conductor posts (15, 25, 35) are all formed at different positions and are connected by the connection patterns in the conductor layer 21 and the conductor layer 31. In this case, the conductor post 25 and the conductor post 35 are respectively formed on flat surfaces of the conductor layer 21 and the conductor layer 31. Good connection reliability with these conductor layers can be obtained. Also when the multilayer wiring board 2 of the present embodiment includes even more wiring bodies, the conductor posts of the wiring bodies may be formed in arbitrary positional relations.

An example of a method for manufacturing the multilayer wiring board 1 of the embodiment illustrated in FIG. 1 is described with reference to FIG. 6A-6L.

As illustrated in FIG. 6A, a support plate 80, a carrier copper foil (80a) and a base metal foil 81 are prepared. The carrier copper foil (80a) is laminated on both sides of the support plate 80, and is bonded thereto by applying pressure and heat. It is also possible to use a copper-clad laminated plate as the support plate 80 and the carrier copper foil (80a). The base metal foil 81 is bonded to the carrier copper foil (80a). Or, it is also possible that, first, the carrier copper foil (80a) and the base metal foil 81 are bonded to each other, and thereafter, the carrier copper foil (80a) is thermal compression bonded to the support plate 80. The bonding method of the carrier copper foil (80a) and the base metal foil 81 is not particularly limited. For example, the carrier copper foil (80a) and the base metal foil 81 are bonded by a thermoplastic adhesive (not illustrated in the drawings) over substantially the entire attachment surface of the two. An example of the thermoplastic adhesive is REVALPHA (manufactured by Nitto Denko Corporation). The carrier copper foil (80a) and the base metal foil 81 may be bonded to each other using an adhesive or by ultrasonic connection in a margin portion near an outer periphery. A material of the support plate 80 is not particularly limited. A prepreg material or the like in a semi-cured state that contains a reinforcing material such as a glass cloth and an insulating resin such as epoxy is preferably used for the support plate 80. A copper foil having a thickness of 18 μm is preferably used for the carrier copper foil (80a). Or, a metal plate formed of copper or the like may be used as the support plate 80 with the carrier copper foil (80a). A material of the base metal foil 81 is not particularly limited as long as it allows the conductor layer 11 (see FIG. 6B) to be formed on a surface thereof. Preferably, a material that can be dissolved by an etching solution that can dissolve the materials of the conductor layer 11 and the conductor post 15 (see FIG. 6G) is used. Preferably, a copper foil having a thickness of 1-6 μm is used for the base metal foil. Another metal foil such as a nickel foil may also be used for the base metal foil 81.

FIG. 6A-6J illustrate an example of a manufacturing method in which the conductor layers 11 and the like are respectively formed on surfaces on both sides of the support plate 80. The conductor layers 11 and the like are respectively formed on both sides of the support plate 80 at the same time. It is also possible that the conductor layer 11 and the like are formed on only one side of the support plate 80. It is also possible that conductor layers 11 and the like having mutually different circuit patterns are respectively formed on both sides of the support plate 80.

The first wiring body 10 (see FIG. 6G) having the resin insulating layer 13, the conductor layer 11 and the conductor post 15 is formed. As illustrated in FIG. 6B, the conductor layer 11 including the first pattern (11a), the second pattern (11b) and the like is formed. Specifically, a plating resist film (not illustrated in the drawings) having openings at positions where the conductor patterns of the conductor layer 11 are formed is formed on a surface of the base metal foil 81. The conductor patterns of the conductor layer 11 are formed in the openings by electrolytic plating using the base metal foil 81 as an electrode on one side. Thereafter, the plating resist film is removed. As illustrated in FIG. 6B, the conductor layer 11 is formed. In this way, when the method is used in which the conductor layer 11 is formed by only electrolytic plating, the conductor layer 11 is not side-etched. The conductor layer 11 can be formed at a fine pitch with line/space of about (15 μm)/(15 μm). The conductor layer 21 is preferably formed to have a thickness of about 5-25 μm. Copper is preferably used as a material for the conductor layer 11. Nickel or the like may also be used.

As illustrated in FIG. 6C, a plating resist film 85 is formed on an exposed surface of the conductor layer 11 and on the base metal foil 81 that is not covered by the conductor layer 11 and is exposed. An opening (85a) is provided at in the plating resist film 85 at a portion where a conductor post 15 is formed. The plating resist film 85 is formed to have a thickness of at least about 50-150 μm. A plating layer 150 is formed in the opening (85a) using the base metal foil 81 as a seed layer. The plating layer 150 is preferably formed by electrolytic plating that allows a thick plating layer to be formed in a relatively short period of time. Thereafter, the plating resist film 85 is removed. As illustrated in FIG. 6D, the conductor post 15 is formed on the surface of the first pattern (11a) from a plating layer by electrolytic plating. The conductor post 15 is preferably formed of the same material as that of the conductor layer 11 and the conductor layer 21 (see FIG. 6I). The conductor post 15 is formed of nickel or copper, and preferably formed of copper. Further, the conductor post 15 is preferably formed to have a height of 50-150 μm. The height of the conductor post 15 is not limited to this. The conductor post 15 is formed at any position where connection between the conductor layer 11 and the conductor layer 21 is desired.

Preferably, in order to improve adhesion to the resin insulating layer 13 (see FIG. 6F), the surface of the conductor post 15 including also the side surface (15b), and the exposed surface such as the side surface of the conductor layer 11, are subjected to a roughening treatment. Examples of the roughening treatment include, for example, a soft etching treatment, a blackening (oxidation)-reduction treatment and the like. However, the roughening treatment is not limited to these. The surfaces that are roughened are preferably processed to have a surface roughness of 0.1-1 μm in arithmetic average roughness. When the roughening treatment is performed, an annealing treatment may be performed before the roughening treatment.

As illustrated in FIG. 6E, a sheet-like or film-like insulating material (13a) is laminated on the conductor posts 15. The insulating layer (13a) is pressed toward the support plate 80 side and is heated. Due to the heating, the insulating material (13a) is softened, and flows into between the conductor patterns in the conductor layer 11 and between the conductor posts 15, and solidifies in a semi-cured state. By being further heated, the insulating material (13a) becomes completely cured. As illustrated in FIG. 6F, the resin insulating layer 13 is formed. The resin insulating layer 13 may cover the exposed surface of the conductor layer 11 including the side surfaces of the conductor patterns in the conductor layer 11 and may cover all of the side surface (15b) and the front end portion of the conductor post 15. When the resin insulating layer 13 is formed by laminating a sheet-like insulating material, common manufacturing equipment for a wiring board can be used. The multilayer wiring board 1 can be easily manufactured.

The resin insulating layer 13 may be formed by die mold molding. For example, after the roughening treatment of the conductor posts 15, a die for mold molding having a cavity is set on the support plate 80. A mold-molding resin is injected into the cavity in which the conductor layer 11 and the conductor posts 15 are accommodated. When the mold-molding resin filled in the cavity is in a semi-cured state, the die is separated. By being further heated, the mold-molding resin becomes completely cured. Also in this method, as illustrated in FIG. 6F, the resin insulating layer 13 can be formed that covers the exposed surface of the conductor layer 11 and covers the side surface (15b) and the front end portion of the conductor post 15. When a formation method using mold molding is used, preferably, a resin material containing a resin composition suitable for die mold molding is used as the material of the resin insulating layer 13. When the resin insulating layer 13 is formed by mold molding, the same material as a resin material of a semiconductor product that is resin-sealed by mold molding can be easily used. A difference in thermal expansion coefficient between the wiring board and the semiconductor product is likely to be reduced. As a result, a stress occurring in a connection part between the wiring board and the semiconductor product can be reduced. When the resin insulating layer 13 is formed by mold molding, preferably, an epoxy resin having a thermal expansion coefficient of 6-30 ppm/° C., an elastic modulus of 5-25 GPa and a glass transition temperature of 100-220° C. is used as the material of the resin insulating layer 13. When the resin material having such properties is used, good flowability is likely to be obtained in the die during molding. Further, after the molding, an excessive stress is unlikely to occur in a connecting part between the wiring board and a mounting component such as a semiconductor product.

The resin insulating layer 13 is not particularly limited in thickness. From a point of view of ensuring reduction in thickness and appropriate rigidity of the wiring board 1, it is preferable that the resin insulating layer 13 be formed to have a thickness of about 50-150 μm. The thickness of the resin insulating layer 13 can be arbitrarily set depending on the height of the conductor post 15. After the formation of the resin insulating layer 13, preferably, buffing is performed. Burrs occurring during the formation of the resin insulating layer 13 are removed. A height of the resin insulating layer 13 is uniformized. Further, the height of the resin insulating layer 13 is adjusted to a predetermined design value.

As illustrated in FIG. 6G, the surface of the resin insulating layer 13 on an opposite side of the base metal foil 81 is polished. The surface of the resin insulating layer 13 is polished by buffing or CMP (Chemical Mechanical Polishing) or the like until the front end of the conductor post 15 is exposed. The first wiring body 10 including the resin insulating layer 13, the conductor layer 11 and the conductor post 15 is completed.

The second wiring body 20 (see FIG. 6J) is formed on the first wiring body 10. The second wiring body 20 is formed by undergoing processes that are substantially the same as the processes in which the first wiring body 10 is formed. As illustrated in FIG. 6H, the metal coating 211 is formed on the surface of the resin insulating layer 13 of the first wiring body 10. The metal coating 211 functions in the same manner as the base metal foil 81 that functions as a seed layer when the conductor layer 11 and the conductor post 15 of the above-described first wiring body 10 are formed by electrolytic plating. That is, the metal coating 211 functions as a seed layer when a large portion of the conductor layer 21 and the conductor post 25 of the second wiring body 20 are formed, for example, by electrolytic plating. The metal coating 211 can form a portion of the conductor layer 21. The metal coating 211 is formed, for example, by electroless plating, or by sputtering or vacuum evaporation or the like. The metal coating 211 is preferably formed of the same material as that of the conductor layer 11 and the conductor post 15. The metal coating 211 is preferably formed of copper to have a thickness of about 0.05-1 μm.

The conductor layer 21 and the conductor post 25 (see FIG. 6I) of the second wiring body 20 are formed using the same method as the formation of the conductor layer 11 of the above-described first wiring body 10, That is, a plating resist film (not illustrated in the drawings) is formed on a surface of the metal coating 211. An opening is provided in the plating resist film at a position where a conductor pattern of the conductor layer 21 is formed. For example, the plating film 212 (see FIG. 6I) is formed in the opening using the metal coating 211 as a seed layer. Thereafter, the plating resist film (not illustrated in the drawings) is removed.

A resist film (not illustrated in the drawings) for forming the conductor post 25 is formed on the plating film 212 and on a portion of the metal coating 211, the portion being exposed from the plating film 212. In the resist film for forming the conductor post 25, an opening is formed at a portion where the conductor post 25 is formed. For example, the conductor post 25 is formed by electrolytic plating in the opening of the resist film for forming the conductor post 25 using the metal coating 211 as a seed layer. Thereafter, the resist film for forming the conductor post 25 is removed. The portion of the metal coating 211 that is exposed by removing the resist film for forming the conductor post 25 is removed by etching. As illustrated in FIG. 6I, the conductor layer 21 having a predetermined conductor pattern and the conductor post 25 are completed. As described above, the metal coating 211 has a thickness of about 0.05-1 μm. Even when the metal coating 211 is removed by etching without masking the plating film 212 and the like, the plating film 212 can maintain a sufficient thickness.

In the example illustrated in FIG. 6I, the conductor layer 21 has a laminated structure that includes the metal coating 211 and the plating film 212. The plating film 212 is usually formed of the same material as the metal coating 211 and is preferably formed of copper. The plating film 212 is formed to have a thickness of, for example, about 5-25 μm. Copper is also preferably used as a material of the conductor post 25. Similar to the conductor post 15, the conductor post 25 is formed to have a height of, for example, about 50-150 μm. However, the plating film 212 and the conductor post 25 may also be formed of other materials. The plating film 212 and the conductor post 25 may also be formed to each have a thickness or height different from the above-described dimensions. Similar to the surface of the conductor post 15, the surface of the conductor post 25 and the exposed surface of the conductor layer 21 are preferably roughened. In this case, an annealing treatment may be performed before the roughening treatment.

The resin insulating layer 23 (see FIG. 6J) is formed that covers the exposed surface of the conductor layer 21 and the surface of the conductor post 25. The resin insulating layer 23 is formed using the same method as the method for forming the resin insulating layer 13 of the first wiring body 10 that is described with reference to FIGS. 6E and 6F. As described above, the resin insulating layer 23 may also be formed by mold molding using a die. Thereafter, using the same method as the method described with reference to FIG. 6G, the surface of the resin insulating layer 23 on an opposite side of the first wiring body 10 is polished. The surface of the resin insulating layer 23 is polished until the front end of the conductor post 25 is exposed. As illustrated in FIG. 6J, the second wiring body 20 having the resin insulating layer 23, the conductor layer 21 and the conductor post 25 is completed.

The support plate 80 and the carrier copper foil (80a) are separated from the base metal foil 81. For example, a half-way wiring board illustrated in FIG. 6J is heated. The thermoplastic adhesive (not illustrated in the drawings) that bonds the carrier copper foil (80a) and the base metal foil 81 is softened. In this state, the carrier copper foil (80a) and the base metal foil 81 are pulled apart from each other. In the case where the two are bonded to each other in the margin portion near the outer periphery, the carrier copper foil (80a), the base metal foil 81 and the support plate 80 may be cut on an inner peripheral side than the bonding place. The bonding place by the adhesive or the like is cut off. As a result, the carrier copper foil (80a) and the base metal foil 81 are separated from each other. A state after the separation of the two is illustrated in FIG. 6K. FIG. 6K illustrates only a wiring board below a lower surface of the support plate 80 in FIG. 6J. Further, illustration of the metal coating 211 and the plating film 212 is omitted, and the conductor layer 21 is illustrated as having a single-layer structure.

The base metal foil 81 is removed, for example, by etching or the like. Preferably, an etching solution capable of dissolving all constituent materials of the base metal foil 81, the conductor layer 11 of the first wiring body 10 and the conductor post 25 of the second wiring body 20 is used. In this case, a front end portion of the conductor post 25 exposed on the second surface (F2b) of the resin insulating layer 23 is also etched along with the base metal foil 81. The etching process may be continued even after the base metal foil 81 is completely removed. As a result, the surface of the conductor layer 11 of the first wiring body 10 is etched. The front end portion of the conductor post 25 of the second wiring body 20 also continues to be etched. As a result, as illustrated in FIG. 6L, the one surface (F11) of the conductor layer 11 of the first wiring body 10 is recessed relative to the first surface (F1a) of the resin insulating layer 13. The end surface (25a) of the conductor post 25 of the second wiring body 20 is recessed relative to the second surface (F2b) of the resin insulating layer 23. The recess of the end surface (25a) of the conductor post 25 from the second surface (F2b) of the resin insulating layer 23 is larger than the recess of the one surface (F11) of the conductor layer 11 from the first surface (F1a) of the resin insulating layer 13.

When the base metal foil 81 is formed of a material different from that of the conductor layer 11 and the conductor post 25, an etching solution that allows only the base metal foil 81 to be dissolved may be used. In this case, after the base metal foil 81 is removed, the conductor layer 11 and the conductor post 25 may be etched separately from the etching of the base metal foil 81. The conductor layer 11 and the conductor post 25 are each etched so as to be recessed by a predetermined amount from the first surface (F1a) or the resin insulating layer 13 or from the second surface (F2b) of the resin insulating layer 23.

In the method for manufacturing the wiring board 1 illustrated in FIG. 1, thereafter, the solder resist layer 51 is formed on the first surface (F1a) of the resin insulating layer 13 of the first wiring body 10. Further, although not illustrated in the drawings, when desired, a solder resist layer (not illustrated in the drawings) may also be formed on the second surface (F2b) of the resin insulating layer 23 of the second wiring body 20. For example, a layer of a photosensitive epoxy material or the like is formed on the first surface (F1a) of the resin insulating layer 13 of the first wiring body 10 and on the entire one surface (F11) of the conductor layer 11. A portion of the epoxy material layer where the solder resist layer 51 is formed is exposed through a mask. A portion of the epoxy material that is not exposed is removed by development. A portion of the epoxy material corresponding to the first pattern (11a) and the second pattern (11b) is removed by development. The removed portion becomes an opening (51a). The solder resist layer 51 may also be formed using another method such as screen printing. A material of the solder resist layer 51 is not particularly limited. Preferably, an epoxy resin containing 40-70% by weight of an inorganic filler such as silica is used. By undergoing the above-described processes, the wiring board 1 of the embodiment illustrated in FIG. 1 is completed.

A surface protection film (not illustrated in the drawings) may be formed on the one surface (F11) of the conductor layer 11 of the first wiring body 10 and on the end surface (25a) of the conductor post 25 of the second wiring body 20. The surface protection film is formed, for example, by plating. The surface protection film may be formed from multiple metal films or a single metal film such as Ni/Au, Ni/Pd/Au, Sn or the like. It is also possible that an organic protective film (OSP) is formed by immersion in a liquid material, or spraying a liquid material, or the like.

A bonding member (not illustrated in the drawings) may be supplied to the end surface (25a) of the conductor post 25. The bonding member bonds the conductor post 25 and an external motherboard or the like. The bonding member may be supplied so as to form a layered shape, or a bump shape, or any other shape. Solder is preferably used as the bonding member. The bonding member can be supplied by applying paste-like solder, or using a plating method, or by mounting and then heating a ball-shaped solder.

For example, a semiconductor element (not illustrated in the drawings) may be connected to the second pattern (11b) of the first wiring body 10 of the completed wiring board 1. Further, the conductor post 25 of the second wiring body 20 may be connected to a motherboard or the like of an electronic device or the like that uses the wiring board 1. The multilayer wiring board 1 of the present embodiment may also be connected to another printed wiring board (not illustrated in the drawings). The multilayer wiring board 1 can be a part of a higher multilayer printed wiring board.

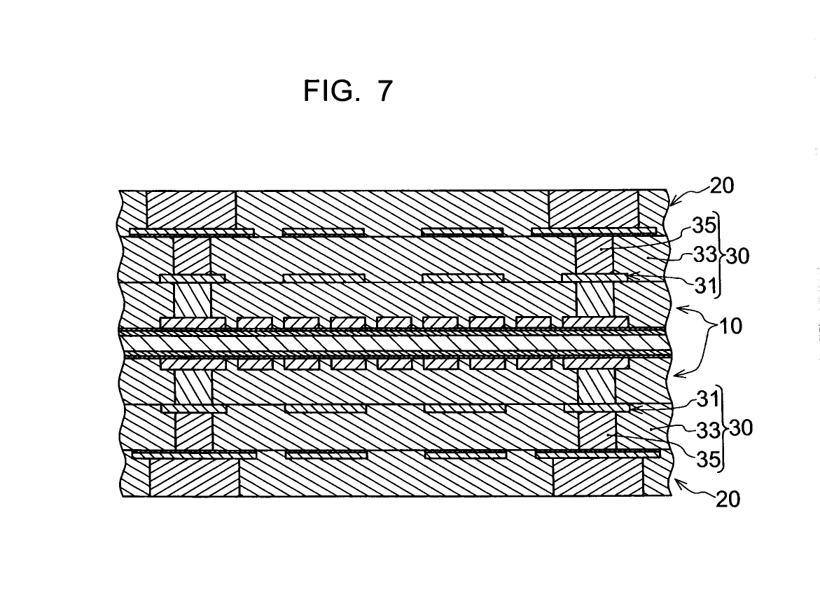

The multilayer wiring board 2 of the embodiment illustrated in FIG. 4 can also be similarly manufactured by repeating a portion of the method described with reference to FIG. 6A-6L. By undergoing the processes up to the process illustrated in FIG. 6G, the first wiring body 10 is formed. Using the same method as the method for forming the second wiring body 20 that is described with reference to FIG. 6H-6J, the third wiring body 30 (see FIG. 7) is formed on the first wiring body 10. That is, the conductor layer 31 and the conductor post 35 are formed using the same method as the method for forming the conductor layer 21 or the conductor post 25 of the second wiring body 20 by electroless plating or electrolytic plating. The resin insulating layer 33 is formed in the same manner as the resin insulating layer 23 of the second wiring body 20 by laminating a film-like insulating material and applying pressure and heat or by resin mold molding. Thereafter, by repeating the same processes as those described with reference to FIG. 6H-6J, as illustrated in FIG. 7, the second wiring body 20 is formed on the third wiring body 30.

By undergoing the same processes as those described with reference to FIG. 6K-6L, the multilayer wiring board 2 illustrated in FIG. 4 is completed. By properly repeating the same processes as those described with reference to FIG. 6H-6J, a multilayer wiring board including a desired number of wiring bodies that are each formed of a laminated body that includes a conductor layer and a resin insulating layer can be manufactured.

A multilayer printed wiring board may include single-sided circuit boards that include conductor posts and conductor layers. When the single-sided circuit boards are laminated on both sides of the core substrate, the number of the conductor layers that have a wiring pattern such as a conductor circuit is an even number. Therefore, even when a circuit that is formed in the printed wiring board can be formed, for example, by an odd number of conductor layers, an even number of conductor layers are formed. There may be cases where this is not necessary efficient. Further, when the conductor post that is formed from a conductive paste and the conductor layer that is formed from a metal foil are bonded to each other, peeling or breaking at a bonding interface is likely to occur due to a stress such as a thermal stress during a process after the bonding or during use of the printed wiring board.

Further, outermost conductor layers of such a multilayer printed wiring board are respectively formed on surfaces of insulating substrates. When wiring patterns are formed at a fine pitch, solders for connecting to a mounting component such as a semiconductor element are likely to cause short-circuiting between adjacent mounting pads. Further, it is expected that, in order to avoid this, solder may not be sufficiently supplied and connection failure is likely to occur. Further, when wiring patterns are formed at a fine pitch, short circuiting due to an etching residue is likely to occur between the wiring patterns. Further, as an area of each of the wiring patterns is reduced, adhesion between the wiring patterns and the insulating substrate is reduced and peeling is likely to occur.

A multilayer wiring board according to an embodiment of the present invention is formed by laminating wiring bodies in the same orientation, the wiring bodies each including: a resin insulating layer that has a first surface and a second surface that is on an opposite side of the first surface; a conductor layer that is embedded in the resin insulating layer on the first surface side with only one surface exposed; and a conductor post that is formed from a plating film on a back side of the one surface of the conductor layer and penetrates the resin insulating layer so that an end surface of the conductor post is exposed to the second surface. A first wiring body that forms an outermost layer on one side of the multilayer wiring board is formed such that the first surface of the resin insulating layer faces outside of the multilayer wiring board. The conductor layer of the first wiring body and the conductor post of a second wiring body that forms an outermost layer on an opposite side of the first wiring body are electrically connect. The one surface of the conductor layer of the first wiring body is exposed at a position that is recessed relative to the first surface of the resin insulating layer of the first wiring body. The end surface of the conductor post of the second wiring body is recessed from the second surface of the resin insulating layer of the second wiring body by a recess amount that is greater than a recess amount of the one surface of the conductor layer of the first wiring body relative to the first surface of the resin insulating layer of the first wiring body. Ends on both sides of the conductor post of the first wiring body are respectively directly bonded to adjacent conductor layers, and the conductor layer of the second wiring body is directly bonded to the conductor post of one of adjacent wiring bodies.

A multilayer wiring board according to an embodiment of the present invention reduces the manufacturing cost. A multilayer wiring board according to an embodiment of the present invention increases connection reliability. Further, a multilayer wiring board according to an embodiment of the present invention suppresses occurrence of short circuiting failure due to contact between bonding members such as solders. Further, in a multilayer wiring board according to an embodiment of the present invention, the wiring bodies having the same structure are laminated. Therefore, occurrence of warpage in the multilayer wiring board is suppressed.

Obviously, numerous modifications and variations of the present invention are possible in light of the above teachings. It is therefore to be understood that within the scope of the appended claims, the invention may be practiced otherwise than as specifically described herein.

What is claimed is:

1. A multilayer wiring board, comprising:
a plurality of wiring bodies each comprising a resin insulating layer, a conductor layer embedded in the resin insulating layer such that the conductor layer has an exposed surface exposed from a first surface of the resin insulating layer, and a conductor post comprising a plating material and formed on an embedded surface of the conductor layer on an opposite side with respect to the exposed surface of the conductor layer such that the conductor post is penetrating through the resin insulating layer and has an end surface exposed from a second surface of the resin insulating layer on an opposite side with respect to the first surface,
wherein the plurality of wiring bodies includes a first wiring body forming a first outermost layer and a second wiring body forming a second outermost layer on an opposite side with respect to the first outermost layer and is laminated such that the first wiring body electrically connects to the second wiring body, the first wiring body is formed such that the exposed surface of the conductor layer is recessed from the first surface of the resin insulating layer of the first wiring body, the second wiring body is formed such that the end surface of the conductor post is recessed from the second surface of the resin insulating layer in a recess amount which is greater than a recess amount of the exposed surface of the conductor layer in the first wiring body, and the plurality of wiring bodies is laminated such that the conductor post of the first wiring body has the exposed surface directly bonded to the conductor layer of an adjacent one of the wiring bodies and that the second wiring body has the conductor layer directly bonded to the conductor post of an adjacent one of the wiring bodies.

2. A multilayer wiring board according to claim 1, wherein the plurality of wiring bodies comprises a third wiring body laminated such that the conductor post of the third wiring body has the exposed surface directly bonded to the conductor layer of an adjacent one of the wiring bodies and that the third wiring body has the conductor layer directly bonded to the conductor post of an adjacent one of the wiring bodies.

3. A multilayer wiring board according to claim 1, wherein the plurality of wiring bodies is formed such that the conductor layer of the first wiring body comprises an electrolytic plating film and the conductor layer of each of the wiring bodies other than the first wiring body comprises a laminated metal layered structure comprising an electrolytic plating film.

4. A multilayer wiring board according to claim 1, wherein the resin insulating layer in each of the wiring bodies comprises a resin material having a thermal expansion coefficient in a range of 6 to 30 ppm/° C., an elastic modulus in a range of 5 to 25 GPa and a glass transition temperature in a range of 100 to 220° C.

5. A multilayer wiring board according to claim 1, wherein the resin insulating layers in the plurality of wiring bodies are made of a same resin material.

6. A multilayer wiring board according to claim 1, further comprising:
a semiconductor component mounted on the first wiring body such that the semiconductor component is connected to the exposed surface of the conductor layer in the first wiring body.

7. A multilayer wiring board according to claim 1, wherein the conductor in the second wiring body is formed in a plurality such that the plurality of conductor posts is arrayed in a dot pattern formed along the embedded surface of the conductor layer.

8. A multilayer wiring board according to claim 1, further comprising:
a solder resist layer formed on the first surface of the resin insulation layer in the first wiring body.

9. A multilayer wiring board according to claim 1, wherein the plurality of wiring bodies is formed such that the conductor post of the first wiring body is stacked on the conductor post of the second wiring body via the conductor layer of the second wiring body.

10. A multilayer wiring board according to claim 2, wherein the plurality of wiring bodies is formed such that the conductor post of the second wiring body is positioned to overlap with the conductor layer of the first wiring body and that the conductor posts of the first and third bodies are connecting the conductor post of the second wiring body to the conductor layer of the first wiring body.

11. A multilayer wiring board according to claim 2, wherein the plurality of wiring bodies is formed such that the conductor posts of the first, second and third wiring bodies are positioned not to overlap each other.

12. A multilayer wiring board according to claim 1, wherein the plurality of wiring bodies is formed such that the conductor post of each of the wiring bodies has a height which is in a range of 50 μm to 150 μm.

13. A multilayer wiring board according to claim 1, wherein the second wiring body is formed such that the recess amount of the end surface of the conductor post is in a range of 3 μm to 10 μm, and the first wiring body is formed such that the recess amount of the exposed surface of the conductor layer is in a range of 0.1 μm to 5 μm.

14. A multilayer wiring board according to claim 2, wherein the plurality of wiring bodies is formed such that the conductor layer of the first wiring body comprises an electrolytic plating film and the conductor layer of each of the wiring bodies other than the first wiring body comprises a laminated metal layered structure comprising an electrolytic plating film.

15. A multilayer wiring board according to claim 2, wherein the resin insulating layer in each of the wiring bodies comprises a resin material having a thermal expansion coefficient in a range of 6 to 30 ppm/° C., an elastic modulus in a range of 5 to 25 GPa and a glass transition temperature in a range of 100 to 220° C.

16. A multilayer wiring board according to claim 2, wherein the resin insulating layers in the plurality of wiring bodies are made of a same resin material.

17. A multilayer wiring board according to claim 2, further comprising:
a semiconductor component mounted on the first wiring body such that the semiconductor component is connected to the exposed surface of the conductor layer in the first wiring body.

18. A multilayer wiring board according to claim 2, wherein the conductor in the second wiring body is formed in a plurality such that the plurality of conductor posts is arrayed in a dot pattern formed along the embedded surface of the conductor layer.

19. A multilayer wiring board according to claim 2, further comprising:
a solder resist layer formed on the first surface of the resin insulation layer in the first wiring body.

20. A multilayer wiring board according to claim 2, wherein the plurality of wiring bodies is formed such that the conductor post of the first wiring body is stacked on the conductor post of the second wiring body via the conductor layer of the second wiring body.
